(19) United States
(12) Patent Application Publication
(10) Pub. No.: US 2020/0308320 A1
(43) Pub. Date: Oct. 1, 2020

(54) CURABLE COMPOSITION COMPRISING DUAL-FUNCTIONAL PHOTOINITIATOR

(71) Applicant: CANON KABUSHIKI KAISHA, Tokyo (JP)

(72) Inventors: Fen Wan, Austin, TX (US); Weijun Liu, Cedar Park, TX (US)

(21) Appl. No.: 16/365,412

(22) Filed: Mar. 26, 2019

(51) Int. Cl. C08F 20/18; G03F 7/039; C08F 2/48

(52) U.S. Cl. CPC C08F 20/18; G03F 7/039; G03F 7/0002; C08F 2500/17; C08F 2/48

(57) ABSTRACT

A curable composition can comprise a polymerizable compound and a dual-functional photoinitiator, wherein the dual-functional photoinitiator includes a photo-active group and at least one functional group capable of forming a covalent bond with the polymerizable compound during curing of the curable composition. The curable composition can have a viscosity of not greater than 10 mP·s at a temperature of 23° C. and an increased glass transition temperature after curing in comparison to a corresponding curable composition including a mono-functional photoinitiator.

### FIELD OF THE DISCLOSURE

The present disclosure relates to a curable composition, particularly to a curable resist composition for nanoimprint lithography, comprising a polymerizable compound and a dual-functional photoinitiator.

### BACKGROUND

Resist compositions for nanoimprint lithography (NIL) employ photoinitiators to initiate curing. In order to achieve a fast curing of the resist, the amount of photoinitiator is often increased up to 5 wt % of the resist composition. After curing of the resist, fragments of the photoinitiator or non-reacted photoinitiator are still present in the resist composition and can migrate to adjacent areas and may cause unwanted reactions. Remaining photoinitiator can further behave as a plasticizer and may reduce the glass transition temperature of the cured material and thereby negatively influence the etch performance.

There is a need to improve resist compositions by eliminating detrimental effects caused by access amounts of photoinitiator.

### SUMMARY

In one embodiment, a curable composition can comprise a polymerizable compound and a dual-functional photoinitiator, wherein the dual-functional photoinitiator comprises a photo-active group and at least one functional group capable of forming a covalent bond with the polymerizable compound during curing of the curable composition; and wherein the curable composition has a viscosity of not greater than 10 mP·s at a temperature of 23° C.

In one aspect, the curable composition can be cured by UV radiation.

In another aspect, the polymerizable compound of the curable composition can include a monomer, an oligomer, a polymer, or any combination thereof.

In a further aspect, at least 90 wt % of the polymerizable compound of the curable composition may have a molecular weight of not greater than 600.

In yet another aspect, the polymerizable compound of the curable composition can include an acrylate oligomer.

In one embodiment, the at least one functional group of the photoinitiator can comprise a carbon to carbon double bond. The carbon to carbon double bond can be part of an acrylate group, a methacrylate group, a vinyl group, or a vinylaryl group.

In another embodiment, the dual-functional photoinitiator of the curable composition can have a molecular weight M_{w} of not greater than 600.

In a further embodiment, the curable composition can be adapted that a glass transition temperature T_{g1} after curing of the curable composition is higher than a glass transition temperature T_{g2} of a corresponding curable composition, wherein the corresponding curable composition differs from the curable composition only by including a mono-functional photoinitiator instead of the dual-functional photoinitiator, and the mono-functional initiator has the same photo-active group as the dual-functional photoinitiator and does not contain a functional group capable of forming a covalent bond with the polymerizable compound.

In one aspect, the curable composition of the present disclosure can have a glass transition temperature T_{g1} of at least 60° C. after curing.

In another aspect, the curable composition can be a resist composition for nanoimprint lithography.

In another embodiment, a method of forming a photo-cured layer on a substrate can comprise: applying a curable composition on the substrate, wherein the curable composition comprises a polymerizable compound and a dual-functional photoinitiator, the dual-functional photoinitiator comprising a photo-active group and at least one functional group capable of forming a covalent bond with the polymerizable compound during curing of the composition; bringing the curable composition into contact with a template or superstrate; irradiating the curable composition with light to form a photo-cured layer; and removing the template or the superstrate from the photo-cured layer.

In one aspect, the curable composition of the method of forming a photo-cured layer can have a viscosity of not greater than 10 mP·s.

In yet another aspect of the method, at least 90 wt % of the polymerizable compound of the curable composition can have a molecular weight of not greater than 600.

In one aspect of the method, the polymerizable compound can include an acrylate oligomer.

In a further aspect of the method, the at least one functional group of the dual-functional photoinitiator may comprise a carbon to carbon double bond.

In a particular aspect of the method, the carbon to carbon double bond of the dual-functional photoinitiator can be part of an acrylate group or of a methacrylate group.

In yet another aspect of the method, a curing time of the curable composition can be not greater than 100 seconds.

In another embodiment, a method of manufacturing an article can comprise forming a photo-cured layer on a substrate by the method described above and processing the substrate to yield the article of manufacture. In one aspect, the article of manufacture can be a semiconductor device or a circuit board.

### BRIEF DESCRIPTION OF THE DRAWINGS

Embodiments are illustrated by way of example and are not limited in the accompanying figures.

FIG. 1 includes a graph illustrating the storage modulus with increasing radiation time according to embodiments.

FIG. 2 includes a graph illustrating the change in Tangent (0) with increasing temperature according to embodiments.

Skilled artisans appreciate that elements in the figures are illustrated for simplicity and clarity and have not necessarily been drawn to scale. For example, the dimensions of some of the elements in the figures may be exaggerated relative to other elements to help improve understanding of embodiments of the invention.

### DETAILED DESCRIPTION

The following description is provided to assist in understanding the teachings disclosed herein and will focus on specific implementations and embodiments of the teachings. This focus is provided to assist in describing the teachings and should not be interpreted as a limitation on the scope or applicability of the teachings.

Unless otherwise defined, all technical and scientific terms used herein have the same meaning as commonly understood by one of ordinary skill in the art to which this invention belongs. The materials, methods, and examples are illustrative only and not intended to be limiting. To the extent not described herein, many details regarding specific materials and processing acts are conventional and may be found in textbooks and other sources within the imprint and lithography arts.

As used herein, the terms “comprises,” “comprising,” “includes,” “including,” “has,” “having” or any other variation thereof, are intended to cover a non-exclusive inclusion. For example, a process, method, article, or apparatus that comprises a list of features is not necessarily limited only to those features but may include other features not expressly listed or inherent to such process, method, article, or apparatus.

As used herein, and unless expressly stated to the contrary, “or” refers to an inclusive-or and not to an exclusive-or. For example, a condition A or B is satisfied by any one of the following: A is true (or present) and B is false (or not present), A is false (or not present) and B is true (or present), and both A and B are true (or present).

Also, the use of “a” or “an” are employed to describe elements and components described herein. This is done merely for convenience and to give a general sense of the scope of the invention. This description should be read to include one or at least one and the singular also includes the plural unless it is obvious that it is meant otherwise.

The present disclosure is directed to a curable composition comprising a polymerizable compound and a dual-functional photoinitiator, and having a low viscosity. The dual-functional photoinitiator can have two functions: 1) initiating the polymerization reaction of the polymerizable compound, and 2) covalently binding the photoinitiator to the polymerizable compound and thereby fixing the photoinitiator or main fragments thereof to the formed polymeric network.

In one embodiment, the functional group of the dual-functional photoinitiator capable of forming a covalent bond with the polymerizable compound can comprise a carbon to carbon double bond. Some non-limiting examples of the functional group including a carbon to carbon double bond can be an acrylate group, a methacrylate group, a vinyl group, or a vinylaryl group.

In certain embodiments, the viscosity of the curable composition can be not greater than 20 mP·s, such as not greater than 15 mP·s, not greater than 12 mP·s, not greater than 10 mP·s, not greater than 9 mP·s, or not greater than 8 mP·s. In other certain embodiments, the viscosity may be at least 2 mP·s, such as at least 3 mP·s, at least 4 mP·s, or at least 5 mP·s. In a particularly preferred aspect, the curable composition can have a viscosity of not greater than 10 mP·s. As used herein, all viscosity values relate to viscosities measured at a temperature of 23° C. with the Brookfield method using a Brookfield Viscometer at 135 rpm.

In one embodiment, the curable composition can be adapted that a glass transition temperature T_{g1} after curing may be higher than a glass transition temperature T_{g2} of a corresponding curable composition. The corresponding curable composition can comprise the same polymerizable compound and may differ only with regard to the type of photoinitiator, which has the same photo-active group but does not contain a functional group capable of forming a covalent bond with the polymerizable compound, and is herein also called a mono-functional photoinitiator. In one aspect, the difference between T_{g1} and T_{g2} can be at least 2° C., such as at least 3° C., at least 4° C., at least 5° C., at least 6° C., at least 8° C., or at least 10° C. In one aspect, the glass transition temperature T_{g1} of the curable composition after curing can be at least 60° C., or at least 65° C., or at least 70° C.

The dual-functional photoinitiator contained in the curable composition of the present disclosure can be made by reacting a mono-functional photoinitiator with a compound introducing a functional group suitable for polymerization reactions to the mono-functional photoinitiator. One non-limiting example for such a reaction can be reacting a mono-functional photoinitiator containing a primary hydroxyl group with acryloyl chloride to introduce an acrylate group, as also described in Example 1 below. It will be appreciated that the dual-functional photoinitiator can be also made by other methods introducing a functional group suitable for polymerization reactions to a mono-functional photoinitiator.

In a particular embodiment, the dual-functional photoinitiator can have a low molecular weight. In aspects, the molecular weight of the dual-functioning photoinitiator can be not greater than 600, such not greater than 550, not greater than 500, not greater than 400, not greater than 300, or not greater than 270.

The polymerizable compound of the curable composition of the present disclosure can comprise at least one functional group suitable for participating in polymerization reactions. The polymerizable compound can include a monomer, an oligomer, a polymer, or any combination thereof. In a particular aspect, at least 90 wt % of the polymerizable compound can have a molecular weight M_{w} of not greater than 600. In yet a further aspect, the polymerizable compound can be a combination of two or three or more different types of monomers, oligomers, and/or polymers.

Non-limiting examples of a reactive functional group of the polymerizable compound can be a hydroxyl group, a carboxyl group, an amino group, an imino group, a (meth)acryloyl group, an epoxy group, an oxetanyl group, or a maleimide group. Such functional groups can be included, e.g., in alkyd resins, polyester resins, acrylic resins, acrylic-alkyd hybrids, acrylic-polyester hybrids, substituted polyether polymers, substituted polyolefin polymers, polyurethane polymers or co-polymers thereof. In a certain embodiment, the polymerizable compound can include an acrylate monomer or oligomer. Other non-limiting examples of polymerizable compounds can include 2-ethyl hexyl acrylate, butyl acrylate, ethyl acrylate, methyl acrylate, benzyl acrylate, isobornyl acrylate, phenol (EO) acrylate, stearyl acrylate, or any combination thereof.

The amount of polymerizable compound in the curable composition can be at least 5 wt % based on the total weight of the curable composition, such as at least 10 wt %, at least 15 wt %, or at least 20 wt %. In another aspect, the amount of polymerizable compound may be not greater than 95 wt %, such as not greater than 85 wt %, not greater than 80 wt %, not greater than 70 wt %, not greater than 60 wt %, not greater than 50 wt %, not greater than 40 wt %, not greater than 35 wt %, not greater than 30 wt %, not greater than 25 wt %, or not greater than 22 wt % based on the total weight of the curable composition. The amount of polymerizable compound can be a value between any of the minimum and maximum values noted above. In a particular aspect, the amount of polymerizable compound can be at least 15 wt % and not greater than 85 wt %.

The polymerizable compound can be cross-linked by a cross-linking agent contained in the curable composition. Non-limiting examples of suitable cross-linking agents can be difunctional monomers such as 1,6-hexanediol diacrylate, dipropylene glycol diacrylate, neopentyl glycol diacrylate, and trifunctional monomers such as trimethylolpropane triacrylate, glycerine (PO)3 triacrylate, pentaerythritol triacrylate, or any combination thereof.

The amount of cross-linking agent contained in the curable composition can be at least 10 wt %, such as at least 15 wt %, at least 20 wt %, or at least 25 wt % based on a total weight of the curable composition. In another aspect, the amount of the cross-linking agent may be not greater than 60 wt %, such as not greater than 55 wt %, not greater than 50 wt %, or not greater than 40 wt %, or not greater than 30 wt %. The amount of the cross-linking agent may be a value within any of the minimum and maximum values noted above. In a particular aspect, the cross-linking agent can be at least 20 wt % and not greater than 50 wt % based on the total weight of the curable composition.

In another embodiment, the polymerizable compound can polymerize with itself without the inclusion of a cross-linking agent.

The curable composition can further contain one or more additives. Non-limiting examples of optional additives can be stabilizers, dispersants, solvents, surfactants, inhibitors or any combination thereof.

The present disclosure is further directed to a method of forming a photo-cured layer. The method can comprise applying a layer of the curable composition described above over a substrate, bringing the curable composition into contact with a template or superstrate; irradiating the curable composition with light to form a photo-cured layer; and removing the template or the superstrate from the photo-cured layer.

The substrate and the solidified layer may be subjected to additional processing, for example, etching processes, to transfer an image into the substrate that corresponds to the pattern in one or both of the solidified layer and/or patterned layers that are underneath the solidified layer. The substrate can be further subjected to known steps and processes for device (article) fabrication, including, for example, curing, oxidation, layer formation, deposition, doping, planarization, etching, formable material removal, dicing, bonding, and packaging, and the like.

The photo-cured layer may be further used as an interlayer insulating film of a semiconductor device, such as LSI, system LSI, DRAM, SDRAM, RDRAM, or D-RDRAM, or as a resist film used in a semiconductor manufacturing process.

As further demonstrated in the examples, it has been surprisingly discovered that a dual-functional photoinitiator can be employed in a resist composition with only very minor increase in viscosity of the composition, and the cured composition can have an increased glass transition temperature in comparison to a cured resist using a mono-functional photoinitiator. In a particular embodiment, the viscosity of the resist composition including a dual-functional photoinitiator can be not greater than 10 mP·s, and a glass transition temperature of the cured resist may be at least 60° C.

### EXAMPLES

The following non-limiting examples illustrate the concepts as described herein.

### Example 1

Preparing of Dual-Functional Photoinitiator.

In a 250 ml round bottom beaker, a mixture was prepared of 22.5 g photoinitiator Irgacure 2959 (from LabNetwork), 10 g acryloyl chloride and 14 g quinoline in 120 ml THF. In addition, 1.12 g 1,4 benzene diol was added to the reaction mixture as a stabilizer. The reaction was conducted under stirring at 25° C. for 5 hours. Thereafter, the solvent was removed by distillation and a white powder was obtained. The white powder product was further purified by recrystallization using the same solvent system. The obtained purity was 98%, confirmed by LCMS. It was verified that the following reaction took place by introducing an acrylate group to Irgacure 2959. The acrylated Irgacure 2959 photoinitiator is called hereafter PI 2959A.

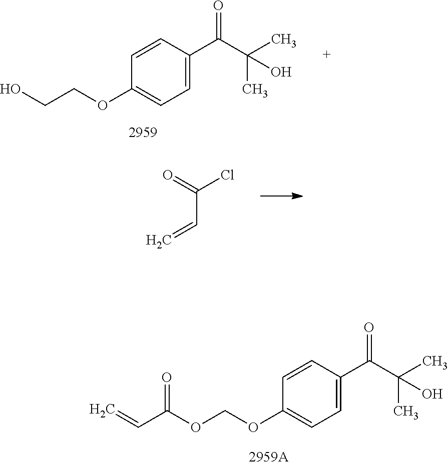

### Example 2

Preparing and Testing of Different Resist Compositions.

A base composition A was prepared by combining 75 g monoacrylates (mixture of isobornyl acrylate (BOA), dicyclopentenyl acrylate (DCPA), benzyl acrylate (BA) and benzyl methacrylate (BMA), 20 g diacrylate (mixture of tricyclodecane dimethanol diacrylate (A-DCPDA) and neopentyl glycol diacrylate (A-NPGDA), and 4 g of a surfactant mixture FS2000M2 (hydrocarbon surfactant) and FS2000M1 (fluorocarbon surfactant).

The base composition A was used for preparing the following resist compositions: C1, S1, S2, and S3.

Resist composition C1 was prepared by combining 99 g of base composition A with 5 g of a mono-functional photoinitiator mixture Irgacure 907 and Irgacure 1173 (volume ratio 2:3), hereinafter called PI 907+1173. All Irgacure products were obtained from LabNetworks.

Resist composition S1 was prepared by combining 99 g of base composition A with 1 g dual functional photoinitiator 2959A prepared according to Example 1, and 4 g of photoinitiator mixture PI 907+1173.

Resist composition S2 was prepared by combining 99 g of base composition A with 2 g photoinitiator 2959A prepared according to Example 1, and 3 g of photoinitiator mixture PI 907+1173.

Resist composition S3 was prepared by combining 99 g of base composition A with 3 g photoinitiator 2959A prepared according to Example 1, and 2 g of photoinitiator mixture PI 907+1173.

A summary of the tested compositions can be seen in Table 1.

TABLE 1

| | Base composition | Photoinitiator | Total amount of |
|---|---|---|---|
| Sample | A [g] | 2959A [g] | photoinitiator [g] |
| C1 | 99 | 0 | 5 |
| S1 | 99 | 1 | 5 |
| S2 | 99 | 2 | 5 |
| S3 | 99 | 3 | 5 |

Table 2 provides a summary of the tested properties of the liquid resist compositions C1, S1, S2, and S3, such as viscosity, surface tension and contact angle, including the standard deviation (STD) of the measurements.

TABLE 2

| | | | Surface Tension | | Contact Angle | |
|---|---|---|---|---|---|---|
| | Viscosity [mP · s] | | [mN/m] | | [degrees] | |
| Sample | Avg | STD | Avg | STD | Avg | STD |
| C1 | 5.8 | 0.08 | 31.80 | 0.20 | 12.80 | 0.40 |
| S1 | 6.18 | 0.07 | 31.60 | 0.32 | 13.38 | 0.41 |
| S2 | 6.32 | 0.06 | 31.76 | 0.14 | 13.07 | 0.69 |
| S3 | 6.50 | 0.03 | 31.70 | 0.15 | 13.60 | 0.62 |

It can be seen from the data in Table 2 that the viscosities of the resist compositions increase only minor (less than 1 mP·s) by employing increasing amounts of dual-functional photoinitiator PI 2959A, and that surface tension and contact angle maintained nearly unchanged.

Table 3 shows a summary of properties which characterize the cure behavior of the resist compositions, as well as mechanical strength (storage modulus) and glass transition temperature T_{g} of the cured compositions. The intensity of the UV radiation was 1 mW/cm².

TABLE 3

| | | | Curing | Glass Transition | Storage | |
|---|---|---|---|---|---|---|
| | Induction | Curing | Dosage | Temperature | Modulus [GPa] | |
| Sample | Time [s] | Time [s] | mJ/cm² | [° C.] | Avg | STD |
| C1 | 25.9 | 82 | 82.0 | 67.1 | 4.50 | 0.39 |
| S1 | 22.6 | 84 | 84.0 | 69.2 | 4.43 | 0.32 |
| S2 | 21.8 | 84 | 84.0 | 71.3 | 4.65 | 0.24 |
| S3 | 23.6 | 89 | 89.0 | 73.8 | 4.40 | 0.30 |

It can be seen from Table 3 that the glass transition temperature T_{g} of the resist compositions increases by replacing the mono-functional photoinitiator (resist sample C1) with dual functional photoinitiator (resist samples S1, S2, and S3), while the total amount of photoinitiator was in all samples the same. The amount of dual functional photoinitiator was varied in samples 51, S2, and S3, and the highest amount of dual-functional photoinitiator (sample S3) caused the highest increase in glass transition temperature. The glass transition temperature could be increased from 67.1° C. (sample C1) to 73.8° C. (sample S3), while the curing dosage differed only by a few mJ, which is within the experimental error.

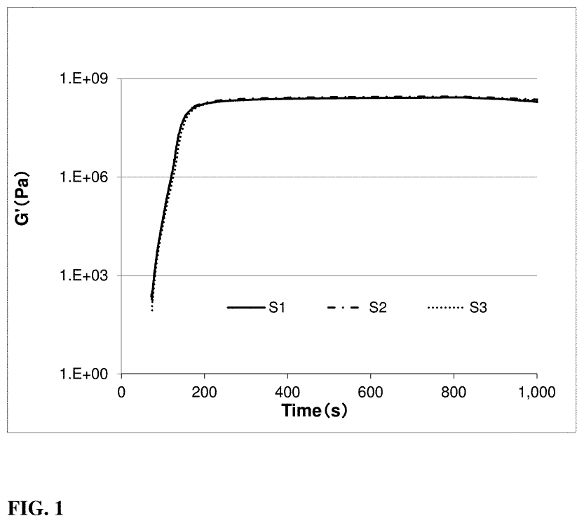

The induction time, curing dosage, storage modulus, and glass transition temperature, was measured with an Anton-Paar MCR-301 rheometer coupled with a Hamamatsu Lightningcure LC8 UV source. The resist sample was radiated with a UV intensity of 1.0 mW/cm² at 365 nm controlled by a Hamamatsu 365 nm UV power meter. Software named RheoPlus was used to control the rheometer and to conduct the data analysis. The temperature was controlled by a Julabo F25-ME water unit and set to 23° C. as starting temperature. For each sample testing, 7 μl resist sample was added onto a glass plate positioned directly underneath the measuring system of the rheometer. Before starting with the UV radiation, the distance between glass plate and measuring unit was reduced to a gap of 0.1 mm. At the beginning of the UV radiation, radicals generated by the photoinitiators were consumed by the inhibitors present in the resist, wherefore the storage modulus did not increase until all the inhibitors were gone. This time period was recorded as induction time. An illustration of the measured storage modulus in dependency to the curing time can be seen in FIG. 1. The UV radiation exposure was continued until the storage modulus reached a plateau, and the height of the plateau was recorded as the storage modulus listed in Table 3.

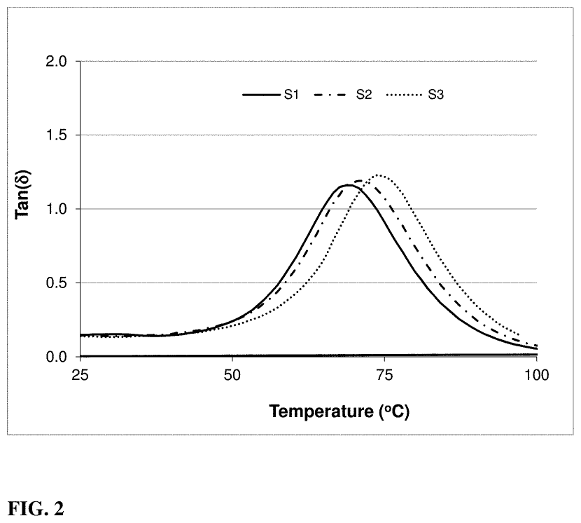

After the UV curing was completed, the temperature of the cured sample was increased by controlled heating to measure the change of the storage modulus in dependency to the temperature to obtain the glass transition temperature T_{g}. As glass transition temperature T_{g} was considered the temperature corresponding to the maximal value of Tangent (θ). FIG. 2 illustrates the measurement of Tangent (θ) with increasing temperature for samples S1, S2, and S3, from which a glass transition temperature T_{g} was determined (position of the peak maxima).

The viscosity of the resist samples was measured at 23° C., using a Brookfield Viscometer LVDV-II+Pro at 135 rpm, with a spindle size #18. For the viscosity testing, about 6-7 mL of resist sample was added into the sample chamber, enough to cover the spindle head. For all viscosity testing, at least three measurements were conducted, and an average value was calculated.

The contact angle and surface tension were measured with a Drop Master DM-701 contact angle meter made by Kyowa Interface Science Co. Ltd. (Japan). For the testing, a quartz slide was first primed with the test sample to mimic the real imprinting surface. Thereafter, 2 ml of the test sample was added to the syringe, of which 2 μl sample per test was added by the machine to the primed surface. Drop images were continuously captured by a CCD camera from the time the resist sample drop touched the primed quartz surface. The contact angle was automatically calculated by the software based on the analysis of the images. The data presented in Table 3 are the contact angles at a time of 3 seconds after touching the primed quartz surface. The DM701 further calculated the surface tension based on images of drops hanging on the syringe needle and using the Young Laplace theory.

The specification and illustrations of the embodiments described herein are intended to provide a general understanding of the structure of the various embodiments. The specification and illustrations are not intended to serve as an exhaustive and comprehensive description of all of the elements and features of apparatus and systems that use the structures or methods described herein. Separate embodiments may also be provided in combination in a single embodiment, and conversely, various features that are, for brevity, described in the context of a single embodiment, may also be provided separately or in any subcombination. Further, reference to values stated in ranges includes each and every value within that range. Many other embodiments may be apparent to skilled artisans only after reading this specification. Other embodiments may be used and derived from the disclosure, such that a structural substitution, logical substitution, or another change may be made without departing from the scope of the disclosure. Accordingly, the disclosure is to be regarded as illustrative rather than restrictive.

What is claimed is:

1. A curable composition comprising a polymerizable compound and a dual-functional photoinitiator, wherein the dual-functional photoinitiator comprises a photo-active group and at least one functional group capable of forming a covalent bond with the polymerizable compound during curing of the curable composition; and wherein the curable composition has a viscosity of not greater than 10 mP·s at a temperature of 23° C.

2. The curable composition of claim 1, wherein the curable composition is curable by UV radiation.

3. The curable composition of claim 1, wherein the polymerizable compound includes a monomer, an oligomer, a polymer, or any combination thereof.

4. The curable composition of claim 3, wherein at least 90 wt % of the polymerizable compound has a molecular weight of not greater than 600.

5. The curable composition of claim 1, wherein the polymerizable compound includes an acrylate oligomer.

6. The curable composition of claim 1, wherein the at least one functional group of the dual functional photoinitiator comprises a carbon to carbon double bond.

7. The curable composition of claim 6, wherein the double bond is part of an acrylate group, a methacrylate group, a vinyl group, or a vinylaryl group.

8. The curable composition of claim 1, wherein the dual-functional photoinitiator has a molecular weight not greater than 600.

9. The curable composition of claim 1, wherein the curable composition is adapted that a glass transition temperature T_{g1} after curing the curable composition is higher than a glass transition temperature T_{g2} of a corresponding curable composition, wherein the corresponding curable composition differs from the curable composition only by including a mono-functional photoinitiator instead of the dual-functional photoinitiator, and the mono-functional initiator has the same photo-active group as the dual-functional photoinitiator and does not contain a functional group capable of forming a covalent bond with the polymerizable compound.

10. The curable composition of claim 9, wherein the glass transition temperature T_{g1} is at least 60° C.

11. The curable composition of claim 1, wherein the curable composition is a resist composition for nanoimprint lithography.

12. A method of forming a photo-cured layer on a substrate, comprising:
applying a curable composition on the substrate, wherein the curable composition comprises a polymerizable compound and a dual-functional photoinitiator, the dual-functional photoinitiator comprising a photo-active group and at least one functional group capable of forming a covalent bond with the polymerizable compound during curing of the composition;
bringing the curable composition into contact with a template or superstrate;
irradiating the curable composition with light to form a photo-cured layer; and
removing the template or the superstrate from the photo-cured layer.

13. The method of claim 12, wherein the curable composition has a viscosity of not greater than 10 mP·s.

14. The method of claim 12, wherein at least 90 wt % of the polymerizable compound has a molecular weight of not greater than 600.

15. The method of claim 12, wherein the polymerizable compound includes an acrylate oligomer.

16. The method of claim 12, wherein the at least one functional group of the dual-functional photoinitiator comprises a carbon to carbon double bond.

17. The method of claim 16, wherein the double bond is part of an acrylate group or of a methacrylate group.

18. The method of claim 12, wherein a curing time of the curable composition is not greater than 100 seconds.

19. A method for manufacturing an article, the method comprising:
forming a photo-cured layer on a substrate by the method as set forth in claim 12;
processing the substrate to yield the article of manufacture.

20. The method according to claim 19, wherein the article of manufacture is a semiconductor device or a circuit board.
